(19) United States
(12) Patent Application Publication
(10) Pub. No.: US 2026/0341625 A1
(43) Pub. Date: Oct. 29, 2026

(54) COOLED X-RAY TUBES AND METHODS OF FORMING THE SAME

(71) Applicant: VAREX IMAGING CORPORATION, Salt Lake City, UT (US)

(72) Inventor: Thomas Anton Morris, Spanish Fork, UT (US)

(73) Assignee: VAREX IMAGING CORPORATION, Salt Lake City, UT (US)

(21) Appl. No.: 19/541,032

(22) Filed: Feb. 16, 2026

Related U.S. Application Data
(60) Provisional application No. 63/796,803, filed on Apr. 29, 2025.

(51) Int. Cl. H01J 35/18; H01J 35/06; H05K 7/20

(52) U.S. Cl. CPC H01J 35/186; H01J 35/064; H05K 7/20727; H01J 2235/1204; H01J 2235/166; H01J 2235/18

(57) ABSTRACT

Enclosures for X-ray tubes, X-ray tubes including the enclosure, and methods of manufacturing enclosures and X-ray tubes are disclosed. An X-ray tube including an anode assembly, a cathode assembly, an enclosure at least at least partially surrounding the cathode assembly and the anode assembly, and a plurality of surfaces protruding from an exterior surface of the enclosure. The cathode assembly can include a plurality of electron emission sources configured to emit electrons towards a plurality of focal spots on the anode assembly.

### CROSS-REFERENCE TO RELATED APPLICATIONS

This application claims priority to U.S. Provisional Application No. 63/796,803, filed 29 Apr. 2025, the entire disclosure of which is hereby incorporated by reference.

### TECHNICAL FIELD

The described embodiments relate generally to enclosures and anodes for X-ray tubes. More particularly, the described embodiments relate to configurations for enclosures and anodes that, inter alia, improve heat dissipation and methods of manufacturing such enclosures and anodes.

### BACKGROUND

X-ray tubes can be used in a wide variety of applications, both industrial and medical, to produce X-rays. An X-ray tube typically includes a cathode, and an anode positioned within an evacuated enclosure (also referred to as a tube, a body, an enclosure, or a housing). The cathode includes an electron source, and the anode includes a target surface that is oriented to receive electrons emitted by the electron source. During operation of the X-ray tube, an electric current is applied to the electron source, which causes electrons to be produced. The electrons are accelerated toward the target surface of the anode by applying a high-voltage potential between the cathode and the anode. When the electrons strike the anode target surface, the kinetic energy of the electrons causes the production of X-rays. Multi-beam X-ray tubes can include a plurality of cathode assemblies and anodes (or targets or target surfaces on an anode), which produce X-rays at a plurality of focal spots. The X-ray tube can include a window through which a portion of the X-rays exits the X-ray tube. The X-rays that exit the X-ray tube can then interact with a material sample, a patient, or another object.

### SUMMARY

An aspect of the present disclosure relates to an X-ray tube including an anode assembly, a cathode assembly, an enclosure, and a plurality of surfaces protruding from an exterior surface of the enclosure. The cathode assembly can include a plurality of electron emission sources configured to emit electrons towards a plurality of focal spots on the anode assembly. The enclosure can at least at least partially surround the cathode assembly and the anode assembly.

In one or all examples, the enclosure and the plurality of surfaces can include a single, continuous material. At least one of the plurality of surfaces can be coupled to the enclosure by a braze or weld. In one or all examples, at least one of the plurality of surfaces can include a material different from a material of the enclosure.

In one or all examples, the X-ray tube can further include a fan coupled to the enclosure. The fan can be coupled to at least one of the plurality of surfaces.

In one or all examples, the enclosure can include a longitudinal body. The anode assembly can be coupled to an end of the longitudinal body. The enclosure can define an X-ray window.

In one or all examples, the X-ray tube can further include an outer enclosure at least partially surrounding the enclosure and the plurality of surfaces. A duct can be defined between the outer enclosure, the enclosure, and the plurality of surfaces. In one or all examples, the X-ray tube can further include a shield at least partially surrounding the outer enclosure. The shield can include a radiation shielding material.

Another aspect of the present disclosure relates to a method of manufacturing an enclosure for an X-ray tube. The method can include forming an enclosure including a plurality of extended surfaces extending from a body portion of the enclosure and welding an end cap to the body portion of the enclosure.

In one or all examples, the extended surfaces and the body portion of the enclosure can be co-formed by extrusion. In one or all examples, forming the enclosure can include brazing or welding the extended surfaces to the body portion.

In one or all examples, the method can further include coating an interior surface of the enclosure with a material having an emissivity greater than a material of the enclosure. In one or all examples, the method can further include machining an X-ray window into the enclosure after coating the interior surface of the enclosure.

In yet another aspect of the present disclosure, an X-ray source includes an enclosure, a cathode assembly, and an anode assembly. The cathode assembly can be at least partially within the enclosure. The anode assembly can be at least partially within the enclosure. The anode assembly can include a plurality of anode extended surfaces extending from a body portion of the anode towards the enclosure.

In one or all examples, the cathode assembly can be coupled to the enclosure. The cathode assembly can include a plurality of cathode electron sources. In one or all examples, the plurality of cathode electron sources can define a plurality of focal spots on a target surface of the anode assembly. The anode extended surfaces can extend away from the target surface.

In one or all examples, the enclosure can include a plurality of enclosure extended surfaces. The enclosure extended surfaces can extend from a body portion of the enclosure towards the anode assembly. In one or all examples, an anode extended surface of the plurality of anode extended surfaces can be between two enclosure extended surfaces of the plurality of enclosure extended surfaces.

### BRIEF DESCRIPTION OF THE SEVERAL VIEWS OF THE DRAWINGS

The disclosure will be readily understood by the following detailed description in conjunction with the accompanying drawings, wherein like reference numerals designate like structural elements, and in which:

FIG. 1A is a side view of an X-ray tube including an enclosure with a round cross-section.

FIG. 1B is a top-down view of the X-ray tube of FIG. 1A.

FIG. 1C is a front-to-back view of the X-ray tube of FIG. 1A.

FIG. 2A is a front-to-back view of an X-ray tube including a fan.

FIG. 2B is a top-down view of the X-ray tube of FIG. 2A.

FIG. 2C is a side view of the X-ray tube of FIG. 2A.

FIG. 3A is a top-down view of an anode assembly.

FIG. 3B is a side view of the anode assembly of FIG. 3A.

FIG. 4 is a side view of an anode assembly.

FIG. 5A is a sectional top-down view of an X-ray tube.

FIG. 5B is a side view of the X-ray tube of FIG. 5A.

FIG. 5C is a side view of the X-ray tube of FIG. 5A.

FIG. 6A is a side view of an X-ray tube.

FIG. 6B is a top-down view of the X-ray tube of FIG. 6A.

FIG. 6C is a front-to-back view of the X-ray tube of FIG. 6A.

FIG. 7 is a side view of an X-ray tube including a shield.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to X-ray tubes, which can be used to generate X-rays. Representative applications for X-ray tubes include, but are not limited to, imaging, medicine, diagnostics, radiology, radiotherapy, radiography and tomography, and a range of industrial X-ray technologies. More specifically, the following disclosure relates to materials, manufacturing processes, and configurations for enclosures and anodes for X-ray tubes. The enclosures can at least partially define evacuated enclosures of the X-ray tubes in which the anodes can be positioned. Utilizing the disclosed materials, manufacturing processes, and configurations to form the enclosures and anodes can improve heat dissipation from X-ray tubes, improve performance of the X-ray tubes, and reduce the cost and weight of the enclosures.

X-ray tubes generally include a cathode, and an anode positioned within an enclosure, which may define an evacuated enclosure. A high voltage power source can be connected across the cathode and the anode such that electrons are emitted from the cathode towards the anode. A target surface can be defined on the anode and X-rays can be generated as the electrons impact the target surface. Bombardment of the anode by electrons and components of the X-ray tube by electrons and X-rays can generate heat in the anode and throughout the X-ray tube.

Conventionally, X-ray tubes and enclosures can be liquid-cooled to dissipate heat generated during X-ray generation. However, the tubing and liquid used to provide liquid cooling to the X-ray tube during the generation of X-rays can significantly increase the weight of the X-ray tube. In applications in which the X-ray tube moves during or between X-ray generation and exposures, this added weight can slow down movement of the X-ray tube, increase requirements on drivers used to move the X-ray tube, and increase the cost and complexity of an X-ray system including the X-ray tube. Further, increased heat dissipation from X-ray tubes can lead to performance improvements from the X-ray tubes as the X-ray tubes can be operated at higher voltage, for longer durations, and the like. Thus, it can be desirable to reduce the weight of X-ray tubes, while maximizing heat dissipation from the X-ray tubes.

The following disclosure provides various configurations for anodes and enclosures for X-ray tubes that can be used to increase heat dissipation from the X-ray tubes. For example, an enclosure can include extended surfaces that extend outward from an exterior surface of the enclosure. The enclosure and the extended surfaces can be formed from a single, continuous material, such as by extruding the enclosure with the extended surfaces. Forming the extended surfaces from a material continuous with the enclosure can maximize heat dissipation from the enclosure to the extended surfaces. The enclosure and the extended surfaces can be formed from the same or different materials, such as by welding or brazing the extended surfaces to the exterior surface of the enclosure. Forming the enclosure and the extended surfaces separately can increase the flexibility in the processes used to manufacture the enclosure and the extended surfaces and can allow for different materials to be used for the enclosure and the extended surfaces. The extended surfaces can increase an exterior surface area of the enclosure, which improves heat dissipation from the enclosure to an external environment.

In one or all examples, an enclosure of an X-ray tube can be air-cooled. Air can be forced across the enclosure by a fan mounted to the enclosure, by external fans or pumps ducted to the enclosure, combinations thereof, or the like. In examples in which the enclosure includes extended surfaces, the combination of air-cooling and the extended surfaces can further improve heat dissipation from the enclosure. The fan can be bolted or otherwise fastened to the extended surfaces of the enclosure. Multiple fans, such as a push fan and a pull fan, can be mounted to the enclosure to further improve heat dissipation from the enclosure. In one or all examples, a fan can include an open bore fan and an electrical connection of the X-ray tube (e.g., a high-voltage connection) can pass through a central bore of the fan.

In one or all examples, an anode of an X-ray tube can include anode extended surfaces that extend towards an enclosure in which the anode is positioned. The anode extended surfaces can extend away from a target surface of the anode, such that the anode extended surfaces are positioned outside of paths of electrons and X-rays present during X-ray generation. The anode extended surfaces can be formed as single, continuous materials with a body of the anode, or can be welded, brazed, or otherwise fastened to the body of the anode. The anode extended surfaces can improve heat dissipation from the anode to the enclosure. In one or all examples, the enclosure can include enclosure extended surfaces that extend towards the anode. The enclosure extended surfaces can be interspersed between the anode extended surfaces. The enclosure extended surfaces can be welded, brazed, or otherwise fastened to the body of the enclosure. The enclosure extended surfaces can also improve heat dissipation from the anode to the enclosure. In one or all examples, coatings can be applied to surfaces of the anode and/or inner surfaces of the enclosure to increase emissivity of the surfaces, further improving heat dissipation from the anode to the enclosure.

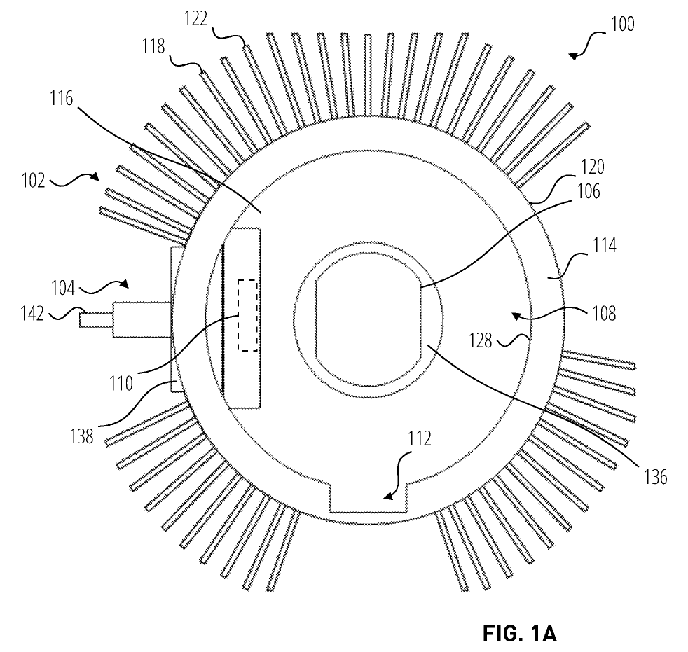

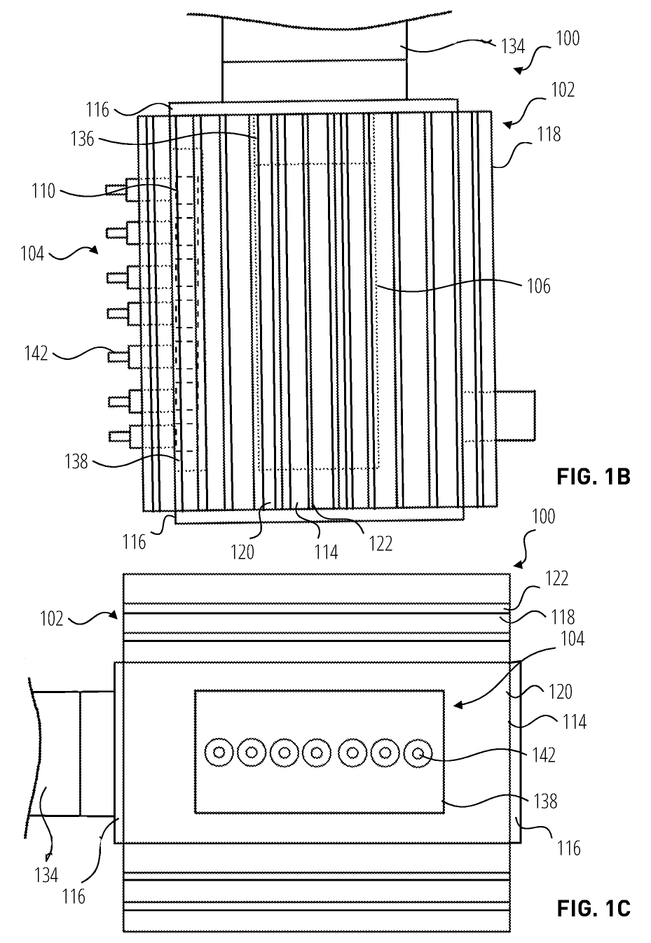

These and other examples are discussed below with reference to FIGS. 1-7 However, those skilled in the art will readily appreciate that the detailed description given herein with respect to these Figures is for explanatory purposes only and should not be construed as limiting. Furthermore, as used herein, a system, a method, an article, a component, a feature, or a sub-feature including at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIGS. 1A-1C illustrate various views of an X-ray tube 100 according to one example. FIG. 1A is a side view, FIG. 1B is a top-down view, and FIG. 1C is a front-to-back view of the exemplary X-ray tube 100. The X-ray tube 100 can be used to generate X-rays. For example, the X-ray tube 100 can include a cathode assembly 104 and an anode assembly 106 positioned within an enclosure 102. In other words, the enclosure 102 can at least partially surround the cathode assembly 104 and the anode assembly 106. The enclosure 102 can define an evacuated enclosure 108, which can maintain an ultra-high vacuum (UHV), an extreme high vacuum (XHV), a high vacuum (HV), or other suitable vacuum levels. A high voltage can be applied between the cathode assembly 104 and the anode assembly 106 such that electrons are emitted from individual cathodes 110 of the cathode assembly 104 towards target surfaces on the anode assembly 106. X-rays can be generated as the electrons impact the target surfaces on the anode assembly 106 and the X-rays can be emitted from the X-ray tube 100 through an X-ray window 112. The X-ray window 112 can be defined in the enclosure 102.

In one or all examples, the cathodes 110 can be hot cathodes or cold cathodes. In examples in which the cathodes 110 are hot cathodes, the cathodes 110 can include hot filaments that emit electrons by thermionic emission. The cathodes 110 can include tungsten filaments, filaments that include tungsten, or the like. The cathodes 110 can also include cold emitters. The X-ray tubes described throughout the present disclosure, which include improved heat dissipation and other benefits, can provide benefits in examples in which the cathodes 110 include either hot or cold cathodes. Providing cold cathodes for the cathodes 110 can provide benefits to the X-ray tube 100, including lower heat dissipation requirements, allowing fast switching or pulsed shot benefits, and the like. Further, using hot cathodes can increase the heat dissipation requirements for the X-ray tube 100, reducing any cooling overhead available for cooling the anode assembly 106.

The enclosure 102 can include a body portion 114, two end caps 116, and a plurality of extended surfaces 118. The plurality of extended surfaces 118 (also referred to as heat fins) can protrude from an exterior surface 120 of the body portion 114 of the enclosure 102. The extended surfaces 118 can increase a surface area of the exterior of the enclosure 102. The term “extended surface” can be used throughout this disclosure to refer to surfaces that extend from an object to increase a rate of heat transfer between the object and an environment around the object. Heat can be generated within the enclosure 102 and a temperature outside of the enclosure 102 (e.g., an ambient temperature) can be lower than a temperature inside the enclosure 102. Thus, the extended surfaces 118 can improve heat dissipation from the X-ray tube 100, through the enclosure 102 to an external environment. In one or all examples, air can be forced across the extended surfaces 118 and the exterior surface 120 of the body portion 114 by a fan, a pump, ducting, or the like to further increase heat dissipation from the X-ray tube 100 via convection and radiation. Including the extended surfaces 118 on the enclosure 102, rather than providing liquid cooling or the like to the X-ray tube 100, can reduce the weight, cost, manufacturing steps and time, and the like of the X-ray tube 100, while also improving performance of the X-ray tube 100.

In one or all examples, each of the extended surfaces 118 can protrude or extend from the exterior surface 120 in a direction normal to the exterior surface 120. FIG. 1A illustrates the extended surfaces 118 as fins. However, the extended surfaces 118 can include any surface profiles or characteristics that increase a surface area of an exterior of the enclosure 102. For example, the extended surfaces 118 can include fins, textured surfaces, porous surfaces (e.g., porous media), or the like. The extended surfaces 118 can be straight extended surfaces (e.g., fins) with uniform cross-sections, or can have varied cross-sectional profiles. For example, the cross-sectional profiles of the extended surfaces 118 can vary along a length of the enclosure 102. In examples in which the extended surfaces 118 are fins, the extended surfaces 118 can be rectangular, V-shaped, U-shaped, triangular, or have any other suitable cross-sectional shape. As illustrated in FIG. 1A, the extended surfaces 118 can be rectangular in shape and a distal end 122 of each of the extended surfaces 118 can define a flat edge. In one or all examples, the distal end 122 of each of the extended surfaces 118 can define a pointed edge, a rounded edge, or the like.

As illustrated in FIG. 1A, the extended surfaces 118 can cover at least a portion of the exterior surface 120 of the body portion 114. In one or all examples, portions of the exterior surface 120 of the body portion 114 can be free from the extended surfaces 118 to provide clearance for components of the X-ray tube 100, and any other portions of the exterior surface 120 can include the extended surfaces 118. For example, the extended surfaces 118 can cover the exterior surface 120 except for portions of the exterior surface 120 that are left open for the cathode assembly 104, the X-ray window 112, a tubulation for evacuating the evacuated enclosure 108, and the like. Although the extended surfaces 118 are illustrated as having equal lengths, in one or all examples, additional extended surfaces 118 with reduced lengths can be included in the enclosure 102. For example, relatively short extended surfaces 118 can be included on either side of the cathode assembly 104.

An outer shape or profile of the plurality of extended surfaces 118 can have a rectangular shape with rounded corners in the cross-sectional or side view. An outer shape of the plurality of extended surfaces 118 can be selected based on an installation location of the X-ray tube 100 and can be selected based on customer specifications or the like. Thus, the outer shape of the plurality of extended surfaces 118 can be customized to fit various installation spaces.

In one or all examples, the extended surfaces 118 can be helically shaped along a length of the enclosure 102 or can have another shape that varies along the length of the enclosure 102. In examples in which the body portion 114 of the enclosure 102 and the extended surfaces 118 are co-extruded or the extended surfaces 118 are attached to the body portion 114, the extended surfaces 118 can be twisted while the extended surfaces 118 are extruded or while the extended surfaces 118 are cooling. Thus, the extended surfaces 118 can have a helical path along the length of the enclosure 102. Providing helically shaped extended surfaces 118 can provide a helical flow path for fluids along the enclosure 102, which can increase a surface area of the enclosure 102 in contact with fluids that travel along the enclosure 102. This increased surface area and dwell time of fluids along the enclosure 102 can increase the cooling efficiency, improving heat dissipation from the enclosure 102. Providing helically shaped extended surfaces 118 can increase manufacturing costs of the X-ray tube 100, while also increasing cooling efficiency, and the shape of the extended surfaces can be optimized depending on desired cooling efficiencies and cost. In one or all examples, the extended surfaces 118 can have wavy or other varying shapes along the length of the enclosure 102, which can also increase surface area and dwell time of fluids along the enclosure 102, increase cooling efficiency, and improve heat dissipation from the enclosure 102.

The body portion 114 can have a rounded, oval, or circular shape in a cross-sectional or side view (e.g., FIG. 1A). An opening in the body portion 114 (e.g., the evacuated enclosure 108) can have a rounded or circular shape in the cross-sectional or side view. The opening in the body portion 114 can house components of the X-ray tube 100. The body portion 114 can have a rectangular shape in a top-down view (e.g., FIG. 1B) and a front-to-back view (e.g., FIG. 1C). The body portion 114 can, in one or all examples, have a constant thickness, except in portions of the body portion 114 that are machined to house or define components of the X-ray tube 100, such as the cathode assembly 104, the anode assembly 106, the X-ray window 112, and the like. The end caps 116 can have shapes that complement the cross-sectional shape of the body portion 114. For example, the end caps 116 can have rounded or circular shapes in the side view illustrated in FIG. 1A. In other words, the end caps 116 can have the same outlines or boundaries as, or mating shapes and features that correspond with, the body portion 114 in the side view. The body portion 114 and the end caps 116 can have any suitable thickness, which can be dependent on the application for the X-ray tube 100.

The extended surfaces 118, the body portion 114, and the end caps 116 of the enclosure 102 can each be formed from a thermally conductive material. In one or all examples, the extended surfaces 118, the body portion 114, and the end caps 116 of the enclosure 102 can each be formed from aluminum-based materials, such as aluminum, an aluminum alloy, or the like. For example, the extended surfaces 118, the body portion 114, and the end caps 116 can be formed from any aluminum alloy series including, but in no way limited to a 5000 series, a 6000 series (e.g., 6061-T6 or other 6000 series), or a 7000 series aluminum alloy. An aluminum concentration in each of the extended surfaces 118, the body portion 114, and the end caps 116 may be at least about 1 weight percent (wt.%), at least about 3 wt.%, at least about 10 wt.%, at least about 90 wt.%, at least about 95 wt.%, at least about 97wt.%, or the like. In one or all examples, the extended surfaces 118 can be formed from a single, continuous material with the body portion 114. The extended surfaces 118 can be formed from different materials from the body portion 114. Although the enclosure 102 is described as being formed from aluminum or an aluminum-based materials, in one or all examples, the enclosure 102 or components thereof (e.g., the body portion 114, the end caps 116, and/or the extended surfaces 118) can be formed from other metals, such as steel (e.g., stainless steel), copper, titanium, tungsten, lead, combinations or alloys thereof, or the like.

The body portion 114 and the extended surfaces 118 of the enclosure 102 can be formed simultaneously or separately. The body portion 114 and/or the extended surfaces 118 can be formed, in one or all examples, by a near-net process, such as extrusion. As such, minimal additional manufacturing steps are performed on the body portion 114 and the extended surfaces 118. This can, for example, reduce waste, manufacturing steps for forming the body portion 114 and the extended surfaces 118, cost, and manufacturing time for the body portion 114 and the extended surfaces 118. In one or all examples, the body portion 114 and/or the extended surfaces 118 can be formed by billet machining, casting, other aluminum machining processes, or the like. Forming the body portion 114 and the extended surfaces 118 by extrusion, billet machining, casting, or the like can be used to form the body portion 114 and the extended surfaces 118 as a single or unitary component formed from a single, continuous material, which can reduce or eliminate welds, seams, or other interfaces in the enclosure 102. This can reduce assembly steps, assembly complexity, and leak points in the enclosure 102. Moreover, forming the extended surfaces 118 from a material that is continuous with the body portion 114 further improves heat dissipation from the body portion 114 to the extended surfaces 118 and from the enclosure 102 to an external environment. By utilizing the described manufacturing processes, the geometry of the extended surfaces 118 can be customized to fit any application, size, or installation location of the X-ray tube 100.

In one or all examples, the body portion 114 can be formed (e.g., using the above-described processes) and the extended surfaces 118 can be coupled to the body portion 114. The extended surfaces 118 can be formed from metal sheets, plates, or the like and can include a material the same or different from the material of the body portion 114. The extended surfaces 118 can be coupled to the body portion 114 by brazing, welding, or other similar or dissimilar metal joining processes. This can allow the extended surfaces 118 to be placed with more flexibility along the exterior surface 120 of the body portion 114, allow for cost, weight, and heat dissipation of the enclosure 102 to be optimized, and the like.

Various treatments can be performed on the X-ray tube 100 or components thereof during the manufacturing process. For example, surface treatments can be formed on the components and the enclosure 102 and the anode assembly 106. Surface treatments can be applied to surfaces of the anode assembly 106 (e.g., a body portion of the anode assembly 106), the body portion 114 (e.g., interior surfaces 128 of the body portion 114), the end caps 116, and/or the extended surfaces 118, including internal and/or external surfaces, to change the color and/or texture of the surfaces. This can alter emissivity of the surfaces, can be used to alter heat transfer between the surfaces (e.g., through radiative heat transfer between surfaces), and can improve aesthetics of the X-ray tube 100. For example, surface treatments can be performed on an external surface of the anode assembly 106, the interior surfaces 128 of the body portion 114, and internal surfaces of the end caps 116 in order to increase emissivity and radiative heat transfer from the anode assembly 106 through the evacuated enclosure 108 to the body portion 114 and the end caps 116. The surface treatments can apply material coatings to the treated surfaces, and the materials of the coatings can have increased emissivity relative to materials of the anode assembly 106, the body portion 114, the end caps 116, and/or the extended surfaces 118. In one or all examples, the coatings can be applied by, and the surface treatments can include, vapor deposition, spray coating, electroplating, anodization, or the like. The surface treatments can improve heat dissipation between components of the X-ray tube 100, such as from the anode assembly 106 to the enclosure 102, thereby improving heat dissipation from the X-ray tube 100 (e.g., to an external environment).

The X-ray window 112 can be machined in the body portion 114 of the enclosure 102. In one or all examples, the X-ray window 112 can be machined in the enclosure 102 after applying any surface treatments to the enclosure 102 in order to prevent any variation in the thickness of the X-ray window 112. The X-ray window 112 can be formed from a single, continuous material with the body portion 114, which can improve heat dissipation from the X-ray window 112 to the body portion 114. The X-ray window 112 can be subjected to heating due to bombardment from X-rays, thus it can be desirable to improve heat dissipation from the X-ray window 112. In one or all examples, X-ray filtration requirements can differ from the X-ray filtration provided by the X-ray window 112 in the body portion 114. In such examples, additional window materials can be brazed, welded, bolted, or otherwise fastened to an inner or outer surface of the body portion 114. In one or all examples, a collimator can be brazed, welded, bolted, or otherwise fastened to an inner or outer surface of the body portion 114.

The enclosure 102 can be formed by joining the end caps 116 to the body portion 114, such as by welding or brazing. The end caps 116 can be formed from metal sheets or plates. The body portion 114 and the end caps 116 can at least partially define an evacuated enclosure 108 of the X-ray tube 100. For example, the end caps 116 can define two side surfaces of the evacuated enclosure 108, the body portion 114 can define side surfaces of the evacuated enclosure 108, the body portion 114 can define a top surface of the evacuated enclosure 108, and the body portion 114 can define a bottom surface of the evacuated enclosure 108. In other words, the end caps 116 can define two surfaces of the evacuated enclosure 108 and the body portion 114 can define remaining surfaces of the evacuated enclosure 108. The portions of the enclosure 102 defining the evacuated enclosure 108 can have a limited number of welds, which reduces assembly steps, assembly complexity, and leak points in the enclosure 102. The enclosure 102 can include the body portion 114 and the two end caps 116, which can reduce a part count, assembly steps, assembly time, and assembly complexity for the enclosure 102.

The X-ray tube 100 is an example of a multi-beam X-ray tube, which includes a plurality of cathodes 110. Each of the cathodes 110 can generate an electron beam, which can be directed towards a focal spot on the anode assembly 106. Each of the cathodes 110 can be directed towards a respective focal spot on the anode assembly 106, and the focal spots can overlap one another, be separated from one another, or the like. The cathodes 110 can be, in one or all examples, cold cathode emitters or the like. As discussed above, the X-ray tube 100 can have improved heat dissipation through the extended surfaces 118 and/or any coatings or surface treatments applied to surfaces of components of the X-ray tube 100. Using cold cathode emitters and including components in the X-ray tube 100 that improve heat dissipation from the X-ray tube 100 can allow the X-ray tube 100 to operate at a reduced operating temperature, such as an operating temperature of less than about 350° C, less than about 300° C, less than about 250° C, less than about 200° C, or the like. This can provide greater flexibility in the materials and processes that can be used to form the X-ray tube 100, including materials, coatings, surface treatments, and the like used for the anode assembly 106, the body portion 114, the end caps 116, the extended surfaces 118, and the like. For example, components of the enclosure 102 can be formed from aluminum-based materials or other light-weight materials, which can reduce the weight of the X-ray tube 100. Materials with relatively high emissivity can be coated on surfaces of the anode assembly 106, the body portion 114, the end caps 116, and the like. Relatively heavy heat dissipation components can be omitted from the X-ray tube 100, such as liquid cooling components, liquids for such components, and other associated elements. Because multi-beam X-ray tubes have relatively large sizes (e.g., as compared to single-beam X-ray tubes), cost and weight can be particularly important in multi-beam X-ray tubes. The materials and processes of the present disclosure can reduce both the weight and cost of the X-ray tube 100. Although the X-ray tube 100 is described in the context of a multi-beam X-ray tube, the methods, materials, and teachings of the present disclosure can also be used in single-emitter, single-beam X-ray tubes and the like.

The cathode assembly 104 can include a cathode body portion 138 to which a plurality of cathodes 110 are coupled. Each of the cathodes 110 can include an electrical connection that passes from within the evacuated enclosure 108 to outside the evacuated enclosure 108 by means of a vacuum feedthrough 142. The vacuum feedthrough 142 can include a stainless-steel ring coupled to a ceramic body. The cathode body portion 138 can be formed from one or more metal materials and can be welded to the body portion 114 of the enclosure 102. For example, the cathode body portion 138 can include stainless steel and aluminum, which can be bonded to one another by any suitable direct metal-to-metal bonding technique (also referred to as dissimilar metal joining processes), such as diffusion bonding, explosion bonding, spin welding, ultrasonic welding, friction welding, other bi-material bonding methods, or the like. The stainless steel of the vacuum feedthrough 142 can be coupled to the stainless steel of the cathode body portion 138 by welding, brazing, or the like. The aluminum of the cathode body portion 138 can be bonded to the body portion 114 by welding, brazing, or the like. Power can be supplied to portions of the cathodes 110 outside the evacuated enclosure 108 defined by the enclosure 102 (e.g., to the vacuum feedthrough 142). The weld between the cathode body portion 138 and the body portion 114 can achieve a reliable hermetic seal. Further, surfaces of the cathode body portion 138 can at least partially define the evacuated enclosure 108 and the surfaces of the cathode body portion 138 that define the evacuated enclosure 108 can be formed from aluminum. This helps to prevent any outgassing from the cathode body portion 138 into the evacuated enclosure 108. The cathode body portion 138 of the cathode assembly 104 can be coupled to the body portion 114 through an opening defined in a side surface of the body portion 114.

By including a cathode assembly 104 in the X-ray tube 100 that is welded to the enclosure 102, the cathode assembly 104 can be processed separately from other portions of the X-ray tube 100 and welded to the enclosure in a final sealing weld between the cathode body portion 138 and the enclosure 102. This allows for processing of the cathode assembly 104 on a separate timeline from other components of the X-ray tube 100, until the cathode assembly 104 is coupled to the enclosure 102. This also allows for maintaining cleanliness of the cathode assembly 104 and sensitive cold cathode emitters (e.g., the cathodes 110), limiting their exposure to atmosphere and/or contaminants. Cold cathode emitters benefit from low particle counts and low gas loads. As such, the cathode assembly 104 can be coupled to the X-ray tube 100 in a clean space, a clean room, or another controlled environment. Including a cathode assembly 104 that welds into or is otherwise coupled to and is separate from the enclosure 102 enables this improved, clean process.

In one or all examples, the X-ray tube 100 can further include a cable 134. The cable 134 can be electrically coupled to the anode assembly 106 via a connector 136, as illustrated in FIG. 1B. The cable 134 can be a high-voltage cable and the connector 136 can be a high-voltage connector. The connector 136, via the cable 134, can facilitate the provision of an electrical voltage bias to the anode assembly 106 during operation of the X-ray tube 100. The anode assembly 106 can be mounted to the enclosure 102 through the connector 136. The connection or coupling between the anode assembly 106 and the enclosure 102 through the connector 136 can at least partially control the spacing between the anode assembly 106 and the cathode assembly 104. The anode assembly 106 and the cathode assembly 104 can be mounted within the X-ray tube 100 to align the cathodes 110 with one or more targets or target surfaces included in the anode assembly 106. The cable 134 and the connector 136 can be coupled to one another through an opening defined in an end cap 116 of the enclosure 102. Although the anode assembly 106, the cable 134, and the connector 136 are illustrated as being coupled to one of the end caps 116 at an end of the X-ray tube 100, the anode assembly 106, the cable 134, and the connector 136 can be coupled to the body portion 114 and can extend through an opening formed in the body portion 114.

In one or all examples, additional components of the X-ray tube 100 can be attached to the enclosure 102. The additional components can include feedthroughs (e.g., electrical feedthroughs), tubes (e.g., vacuum or evacuation tubes), and the like. The additional components can include stainless steel components, copper components, or components formed of other suitable materials. The additional components can be attached or coupled to the enclosure 102 through brazing or other dissimilar metal joining processes. As illustrated in FIGS. 1A-1C, the extended surfaces 118 can at least partially surround the enclosure 102 aside from where the additional components, the cathode assembly 104, and the X-ray window 112 is positioned.

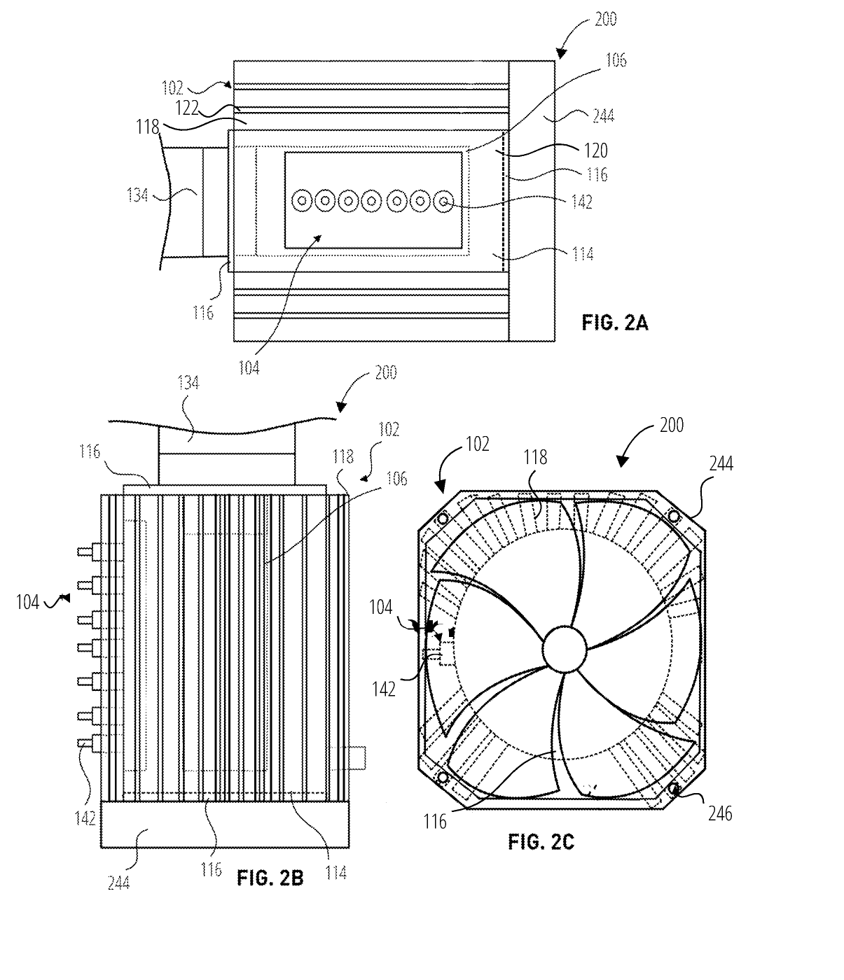

FIGS. 2A-2C illustrate various views of an example of an X-ray tube 200. FIG. 2A is a front-to-back view, FIG. 2B is a top-down view, and FIG. 2C is a side view of the X-ray tube 200. The X-ray tube 200 can be the same as or similar to the X-ray tube 100, discussed above in reference to FIGS. 1A-1C, except that the X-ray tube 200 includes a fan 244 attached to the enclosure 102. Components of the X-ray tube 200 that are the same as or similar to components of the X-ray tube 100 are indicated with the same reference numbers as FIGS. 1A-1C, and additional description of these components is omitted for simplicity.

As illustrated in FIGS. 2A-2C, the X-ray tube 200 can include a fan 244 secured to the enclosure 102. The fan 244 can be provided to move air or another fluid over the exterior of the X-ray tube 200. The fan 244 can thereby increase convective heat transfer from the X-ray tube 200 and increase heat dissipation from the X-ray tube 200. The fan 244 can move air over exterior surfaces of the X-ray tube 200, including the extended surfaces 118, the exterior surface 120 of the body portion 114, the end caps 116, and the like. By moving air over the exterior surfaces of the X-ray tube 200, the fan 244 can increase convection and heat dissipation from the X-ray tube 200. An ambient temperature (e.g., a temperature of air or other fluids surrounding the X-ray tube 200) can be less than a temperature of the X-ray tube 200 and within the X-ray tube 200, such that the fan 244 move relatively cool air or fluids across the exterior surfaces of the X-ray tube 200. This can reduce operating temperatures of the X-ray tube 200, such as during the generation of X-rays, and can improve performance of the X-ray tube 200. The fan 244 can improve heat dissipation for the X-ray tube 200 with relatively low cost and low weight.

In one or all examples, the fan 244 can be provided in addition to or in place of the extended surfaces 118. For example, the fan 244 can be provided alone to increase heat dissipation from the X-ray tube 200, or the extended surfaces 118 can be provided in addition to the fan 244 to further increase heat dissipation from the X-ray tube 200. Moreover, FIGS. 2A-2C illustrate a specific example of a fan 244 attached directly to the X-ray tube 200. However, air or other fluids can be moved across the X-ray tube 200 by fans, pumps, or the like in different configurations. For example, the X-ray tube 200 can be installed in an operating room, an examination room, an inspection room, or the like and air can be ducted from a central air conditioner or the like to flow over the X-ray tube 200. Thus, the X-ray tube 200 can be cooled by components already existing in an installation location without adding cost or weight to the X-ray tube 200 itself. Any types of fans, pumps, or the like can be used to move air or other fluids across the X-ray tube 200 to increase convection and heat dissipation from the X-ray tube 200, and the air or fluids can flow through any tubing, ducting, or the like from the fan or pump to the X-ray tube 200. Further, the X-ray tube 200 can be installed or mounted in a location with surrounding structures. The fan 244 can force air over the exterior surfaces of the X-ray tube 200 between the X-ray tube 200 and the surrounding structures, which can increase the velocity of air flowing over the exterior surfaces of the X-ray tube 200. This can further increase convection and heat dissipation from the X-ray tube 200. The fan 244 and/or the exterior surfaces of the X-ray tube 200 (e.g., the extended surfaces 118) can be customized based on an installation location for the X-ray tube 200 to optimize fluid flow over the exterior surfaces of the X-ray tube 200, between the X-ray tube 200 and the surrounding structures.

In one or all examples, the fan 244 can be secured directly or indirectly to the X-ray tube 200. For example, the fan 244 can be secured to one or more of the extended surfaces 118, one of the end caps 116, or the like. The fan 244 can be secured to the extended surfaces 118, the end cap 116, or another structure of the enclosure 102 by any suitable means, such as brazing, fasteners (e.g., bolts, screws, rivets, or the like), clips, glues, threads, welding, soldering, or the like. In one or all examples, threaded holes can be defined in the extended surfaces 118, mounting surfaces secured to the extended surfaces 118, the end cap 116, or the like. As illustrated in FIG. 2C, the fan 244 can define through-holes 246. Bolts, screws, or other threaded fasteners can be positioned through each of the through-holes 246 and screwed into the respective threaded holes to secure the fan 244 to the X-ray tube 200.

In one or all examples, the X-ray tube 200 can include multiple fans 244. For example, the X-ray tube 200 can include multiple fans 244 having a push-pull configuration. This configuration can allow one fan 244 (e.g., disposed at a first end of the X-ray tube 200) to pull air into the X-ray tube 200 and another fan 244 (e.g., disposed at a second end of the X-ray tube 200 opposite the first end) to push air out and away from the X-ray tube 200. The fans 244 can be configured as push fans or pull fans depending on the fan blade pitch direction and the rotation fan of each respective fan 244. Including multiple fans 244 in a push-pull or other configuration can increase fluid flow over the X-ray tube 200, improving heat transfer and heat dissipation from the X-ray tube 200. In one or all examples, one or more of the fans 244 can be or include a non-tradition perimeter fan with an open center bore. A high voltage connection (e.g., the cable 134) can be provided through the open center bore and the fan blades can flow air around the centralized electrical connection (e.g., around the cable 134). This open bore fan 244 can thus be used to provide the fans 244 at opposite ends of the X-ray tube 200, even when the cable 134 is provided at one end of the X-ray tube 200.

As illustrated in FIGS. 2A and 2B, the body portion 114 can be recessed such that surfaces of the end cap 116 proximal the fan 244 are flush with surfaces of the extended surfaces 118 proximal the fan 244. In one or all examples, surfaces of the body portion 114 can be flush with surfaces of the extended surfaces 118 and the end cap 116 can space the fan 244 apart from the extended surfaces 118. In such examples, the fan 244 can be secured to the end cap 116, to mounting structures extending between the extended surfaces 118 and the fan 244 (e.g., extending from the extended surfaces 118 to flush with the surfaces of the extended surfaces 118 proximal the fan 244), spacers can be positioned between the extended surfaces 118 and the fan 244, or the like.

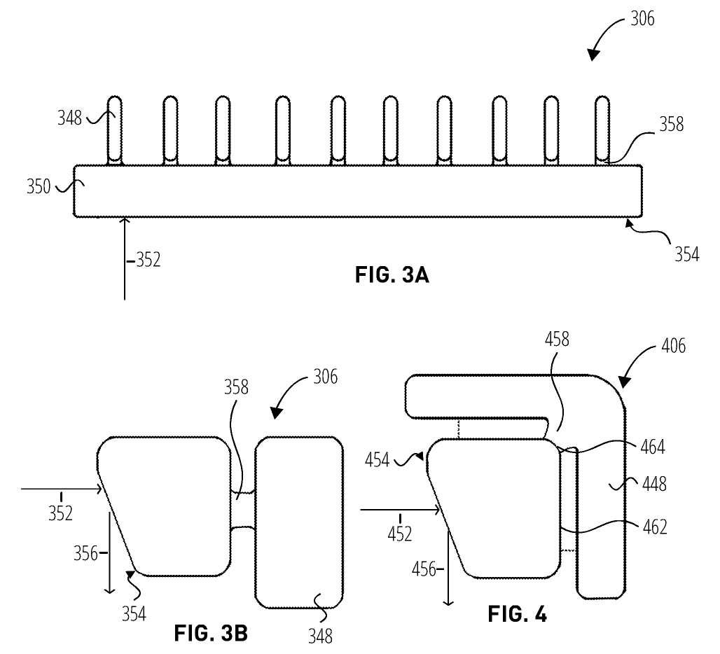

FIGS. 3A and 3B illustrate various views of an anode assembly 306. FIG. 3A is a top-down view and FIG. 3B is a side view of the anode assembly 306. The anode assembly 306 can be the same as or similar to the anode assembly 106, discussed above. The anode assembly 306 can be used in any of the X-ray tubes of the present disclosure, including the X-ray tubes 100, 200, discussed above.

The anode assembly 306 can include a body portion 350 on which a target surface 354 is defined and anode extended surfaces 348 extending from the body portion. The target surface 354 can be oriented to receive electrons 352 emitted by an electron source. When the electrons 352 strike the target surface 354, the kinetic energy of the electrons 352 causes the production of X-rays 356.

The electrons 352 striking the target surface 354 and the target surface 354 producing the X-rays 356 can generate heat in the anode assembly 306. Because the anode assembly 306 is generally provided within an evacuated enclosure of an X-ray tube, it can be challenging to dissipate heat from the anode assembly 306. As such, the anode assembly 306 can include the anode extended surfaces 348. The anode extended surfaces 348 can increase a surface area of the anode assembly 306, which can increase the emissivity and radiative heat transfer from the anode assembly 306, thereby increasing heat dissipation from the anode assembly 306. The anode extended surfaces 348 can be formed with minimal cost and weight increases and can improve the performance of an X-ray tube including the anode assembly 306.

The target surface 354 can extend along a length of the body portion 350. In examples in which the anode assembly 306 is used in a multi-beam X-ray tube, one or a plurality of focal spots can be defined along the target surface 354. The focal spots are defined by the electrons 352 impacting the target surface 354 to produce the X-rays 356, and heat generation can be relatively greater at or near the focal spots. In other words, heat can be generated unevenly across the target surface 354 and the body portion 350. The anode extended surfaces 348 can be aligned with the focal spots (e.g., and the electrons 352 and emitters that emit the electrons 352), to maximize heat transfer and heat dissipation from the focal spots and the anode assembly 306.

As illustrated in FIGS. 3A and 3B, the anode extended surfaces 348 can extend from the body portion 350 away from the direction from which the electrons 352 are emitted. In other words, the anode extended surfaces 348 can extend from the body portion 350 away from an electron source, a cathode, and the like. The anode extended surfaces 348 can extend in a direction parallel to the emission direction of the electrons 352. The anode extended surfaces 348 can extend from the body portion 350 in any directions that are outside areas of the electrons 352 and the X-rays 356. In other words, the anode extended surfaces 348 can extend from any surfaces of the body portion 350 such that the anode extended surfaces 348 do not interfere with the electrons 352 and the X-rays 356.

The body portion 350 and the anode extended surfaces 348 can be formed from the same or different materials. For example, the body portion 350 and the anode extended surfaces 348 can be formed from tungsten (W), molybdenum (Mo), rhenium (Re), copper (Cu), chromium (Cr), rhodium (Rh), combinations or alloys thereof, or the like. The body portion 350 and the anode extended surfaces 348 can be formed from a single, continuous material, or can be formed from separate materials. In one or all examples, the anode extended surfaces 348 can be coupled to the body portion 350 by brazing, welding, or other similar or dissimilar metal joining processes. In one or all examples, the anode extended surfaces 348 can be coated with materials to increase an emissivity and radiative heat transfer from the anode extended surfaces 348. The anode extended surfaces 348 can be coated with a material having an emissivity greater than a material of the anode extended surfaces 348, such as a black body emissive coating, or any other coating that increases the emissivity of the anode extended surfaces 348. This can further improve heat dissipation from the anode assembly 306.

The anode extended surfaces 348 can be shaped and spaced to prevent electrical discharge within an X-ray tube. For example, as illustrated in FIGS. 3A and 3B, the anode extended surfaces 348 can include rounded or curved edges and surfaces. The anode extended surfaces 348 can have rectangular shapes with rounded corners in top-down and side views. The anode extended surfaces 348 can be free from sharp edges. In operation within an X-ray tube, the anode assembly 306 can be at a high voltage, and any sharp edges of the anode assembly 306 (and the anode extended surfaces 348) can cause arcing between the anode assembly 306 and the enclosure of the X-ray tube. Further, the spacing between the anode extended surfaces 348 can be selected to prevent any arcing between the anode extended surfaces 348 and each other or the enclosure of the X-ray tube. The specific spacing and shape of the anode extended surfaces 348 can depend on characteristics of the X-ray tube, including the voltage applied to the anode assembly 306.

The anode extended surfaces 348 can have heights greater than a height of the body portion 350, such that top surfaces of the anode extended surfaces 348 can be above the top surface of the body portion 350 and bottom surfaces of the anode extended surfaces 348 can be below the bottom surface of the body portion 350. Increasing the size of the anode extended surfaces 348 can increase the surface area and heat dissipation of the anode extended surfaces 348. The anode extended surfaces 348 can be connected to the body portion 350 through bridges 358, which can be relatively narrow as compared to the anode extended surfaces 348 and the body portion 350. Surfaces and edges of the bridges 358 can be curved or rounded.

FIG. 4 illustrates a side view of an anode assembly 406 that includes anode extended surfaces 448 extending from or around two surfaces of a body portion 450. The anode assembly 406 can be the same as or similar to the anode assemblies 106, 306, discussed above. The anode assembly 406 can be used in any of the X-ray tubes of the present disclosure, including the X-ray tubes 100, 200, discussed above.

As illustrated in FIG. 4, the anode extended surfaces 448 can extend from and around two surfaces of the body portion 450 opposite a target surface 454. The anode extended surfaces 448 can surround or encircle a first surface 460 and a second surface 462 of the body portion 450. As illustrated in FIG. 4, the anode extended surfaces 448 can extend past edges of the first surface 460 and the second surface 462. Increasing the size of the anode extended surfaces 448 can increase the surface area and heat dissipation of the anode extended surfaces 448.

The anode extended surfaces 448 can be connected to the body portion 450 through bridges 458, which can be relatively narrow as compared to the anode extended surfaces 448 and the body portion 450. As illustrated in FIG. 4, the bridges 458 can be connected to a corner 464 of the body portion 450 between the surfaces 460, 462. However, the bridges 458 can be connected to one or both of the surfaces 460, 462, as indicated by the dashed lines in FIG. 4. Surfaces and edges of the bridges 458 can be curved or rounded.

FIGS. 3A-4 illustrate two configurations for extended surfaces that can be included in anode assemblies. However, any configurations for the extended surfaces are possible and can depend on characteristics of an X-ray tube in which the respective anode assembly is installed. The extended surfaces can extend around any surfaces of the body portion of an anode, and increasing the surface area of the extended surfaces can increase heat dissipation and radiative heat transfer from the extended surfaces, away from the body portion and the anode assembly. The extended surfaces can extend around any portions of the body portion that do not interfere with the paths of incident electrons or produced X-rays.

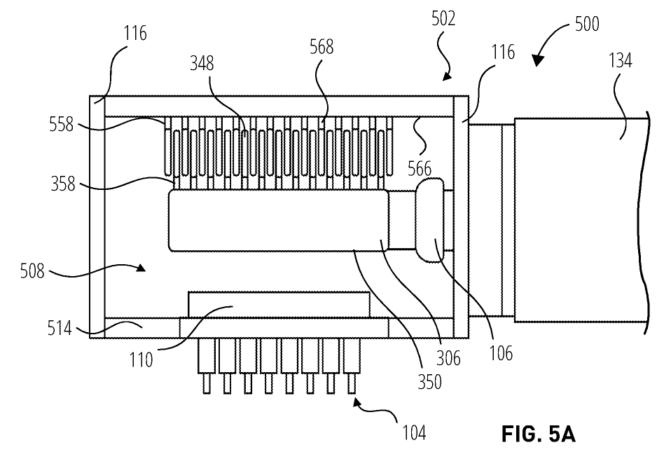

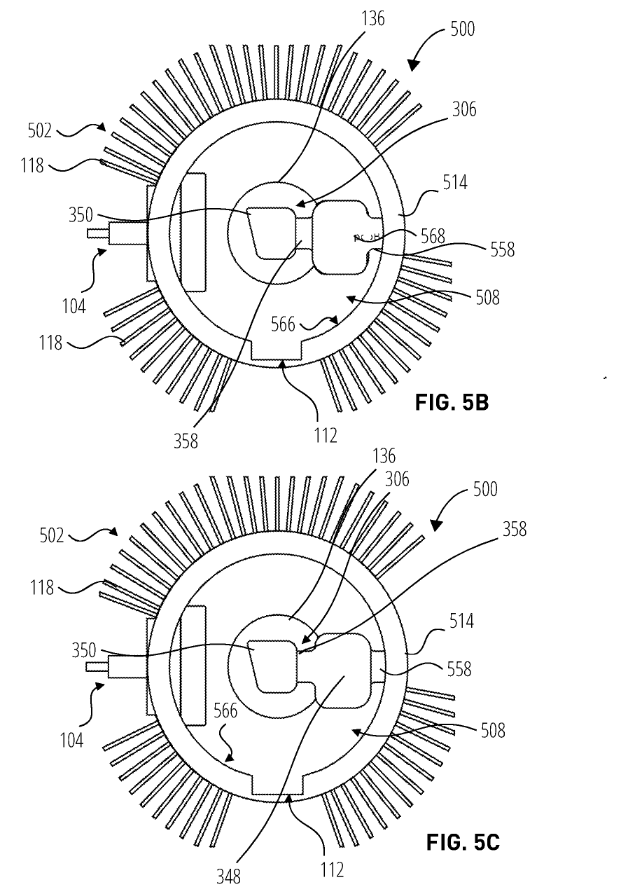

FIGS. 5A-5C illustrate various views of an X-ray tube 500. FIG. 5A is a sectional top-down view, FIG. 5B is a side view, and FIG. 5C is a side view of the X-ray tube 500. The X-ray tube 500 can be the same as or similar to the X-ray tubes 100, 200, discussed above. FIGS. 5A-5C illustrate an example in which the anode assembly 306 including anode extended surfaces 348 (discussed above with respect to FIGS. 3A and 3B) is positioned in an evacuated enclosure 508 defined by an enclosure 502 of the X-ray tube 500. A body portion 514 of the enclosure 502 includes enclosure extended surfaces 568, which can interface with the anode extended surfaces 348. Components of the X-ray tube 500 that are the same as or similar to components of the X-ray tube 100 are indicated with the same reference numbers as FIGS. 1A-1C, and additional description of these components is omitted for simplicity. The X-ray tube 500 can be used with a fan or other cooling components, as discussed above with respect to FIGS. 2A-2C.

The enclosure 502 and the body portion 514 of the X-ray tube 500 can be the same as or similar to the enclosure 102 and the body portion 114, respectively, of the X-ray tube 100, discussed above with respect to FIGS. 1A-1C, except that the body portion 514 further includes enclosure extended surfaces 568 extending from the body portion 514 towards the anode assembly 306. More specifically, the enclosure extended surfaces 568 can extend from an inner surface 566 of the body portion 514 inward, towards the anode assembly 306.

The enclosure extended surfaces 568 can be shaped to prevent electrical discharge within the X-ray tube 500. For example, as illustrated in FIGS. 5A-5C, the enclosure extended surfaces 568 can include rounded or curved edges and surfaces. The enclosure extended surfaces 568 can have rectangular shapes with rounded corners in top-down and side views. The enclosure extended surfaces 568 can be free from sharp edges. In operation within the X-ray tube 500, the anode assembly 306 can be at a high voltage, and any sharp edges of the anode assembly 306 or the enclosure 502 (e.g., including the enclosure extended surfaces 568) can cause arcing between the anode assembly 306 and the enclosure 502.

As illustrated in FIGS. 5A-5C, the anode extended surfaces 348 of the anode assembly 306 can extend from the body portion 350 toward the inner surface 566 of the body portion 514. The anode extended surfaces 348 and the enclosure extended surfaces 568 can be interspersed between one another. For example, each anode extended surface 348 can be disposed between two adjacent enclosure extended surfaces 568. Each enclosure extended surface 568 can be disposed between two adjacent anode extended surfaces 348. Although outermost ones of the extended surfaces are illustrated as being enclosure extended surfaces 568, the outermost extended surfaces can be anode extended surfaces 348, or one enclosure extended surface 568 and one anode extended surface 348. The anode extended surfaces 348 and the enclosure extended surfaces 568 can be separated from contacting one another.

The enclosure extended surfaces 568 can be positioned in close proximity to the anode extended surfaces 348. This can improve the radiative heat transfer (e.g., heat dissipation) from the anode extended surfaces 348 to the enclosure extended surfaces 568. Heat transferred to the enclosure extended surfaces 568 can be dissipated away from the anode assembly 306 through conduction. The spacing between the enclosure extended surfaces 568 and the anode extended surfaces 348 can be minimized to maximize heat dissipation from the anode extended surfaces 348 to the enclosure extended surfaces 568, while preventing electrical breakdown (e.g., arcing) between the anode assembly 306 and the enclosure 502. The specific spacing, shape, and number of the enclosure extended surfaces 568 and the anode extended surfaces 348 can depend on characteristics of the X-ray tube 500, including the voltage applied to the anode assembly 306. The shapes, separation distances, and the like of the enclosure extended surfaces 568 and the anode extended surfaces 348 can be defined based on standoff requirements for maximum operating voltages of the X-ray tube 500 and the like. For some applications in which the X-ray tube 500 operates at lower voltages, the enclosure extended surfaces 568 and the anode extended surfaces 348 can be spaced closer together, which can improve thermal performance.

The enclosure extended surfaces 568 can have shapes complementary to, matched to, or otherwise based on shapes of the anode extended surfaces 348. This can maximize overlapping surface areas between the enclosure extended surfaces 568 and the anode extended surfaces 348, which can increase heat dissipation from the extended surfaces 348 to the enclosure extended surfaces 568. In one or all examples, the anode extended surfaces 348 and the enclosure extended surfaces 568 can have different surface areas, such as the anode extended surfaces 348 having larger or smaller surface areas than the enclosure extended surfaces 568.

Similar to the anode extended surfaces 348, the enclosure extended surfaces 568 can be shaped and positioned such that the enclosure extended surfaces 568 do not block or interfere with paths of electrons and X-rays in the evacuated enclosure 108. Specifically, the enclosure extended surfaces 568 can be positioned outside of a path of electrons between the cathode assembly 104 and the anode assembly 306 and outside of a path of X-rays between the anode assembly 306 and the X-ray window 112.

The anode assembly 306 can be positioned in the enclosure 502 by rotating the anode assembly 306 so that the anode extended surfaces 348 do not overlap with the enclosure extended surfaces 568. The anode assembly 306 can be inserted into the enclosure 502 until the end cap 116 in which the anode assembly 306 is mounted contacts the body portion 514 and the anode extended surfaces 348 are in a desired position relative to the enclosure extended surfaces 568 in a direction parallel to lengths of the enclosure 502 and the anode assembly 306. The anode assembly 306 can then be rotated so that the anode extended surfaces 348 are positioned to overlap with the enclosure extended surfaces 568. The end cap 116 can then be sealed to the body portion 514, such as by brazing, welding, or other similar or dissimilar metal joining processes.

The body portion 514 of the enclosure 502 and the enclosure extended surfaces 568 can be formed from the same or different materials. For example, the body portion 514 and the enclosure extended surfaces 568 can be formed from aluminum-based materials, steel (e.g., stainless steel), copper, titanium, tungsten, lead, combinations or alloys thereof, or the like. In one or all examples, the enclosure extended surfaces 568 can be coupled to the body portion 514 by brazing, welding, or other similar or dissimilar metal joining processes. In one or all examples, the enclosure extended surfaces 568 and/or the inner surface 566 of the body portion 514 can be coated with materials to increase an emissivity and radiative heat transfer to the enclosure extended surfaces 568 and the inner surface 566. The enclosure extended surfaces 568 and/or the inner surface 566 can be coated with a material having an emissivity greater than a material of the enclosure extended surfaces 568 and the inner surface 566, such as a black body emissive coating, or any other coating that increases the emissivity of enclosure extended surfaces 568 and/or the inner surface 566. This can further improve heat dissipation from the anode assembly 306.

FIG. 5B illustrates a connection between an enclosure extended surface 568 and the inner surface 566 of the body portion 514. As illustrated in FIG. 5B, the enclosure extended surfaces 568 can be connected to the inner surface 566 of the body portion 514 through bridges 558. The bridges 558 can be relatively narrow as compared to the enclosure extended surfaces 568. Surfaces and edges of the bridges 558 can be curved or rounded. The bridges 558 can be the same as or similar to the bridges 358. FIG. 5C illustrates a connection between an anode extended surface 348 and the body portion 350 of the anode assembly 306. As discussed previously, the anode extended surfaces 348 can be connected to the body portion 350 through the bridges 358. FIGS. 5B and 5C can be side views of the X-ray tube 500 taken from different points along a length of the X-ray tube 500 or can illustrate examples in which an enclosure extended surface 568 is an outermost extended surface (FIG. 5B) or an anode extended surface 348 is the outermost extended surface (FIG. 5C).

As illustrated in FIG. 5A, the anode extended surfaces 348 can be distributed along a length of the anode assembly 306. The body portion 514 of the enclosure 502 can have a length greater than the length of the anode assembly 306. As such, the enclosure extended surfaces 568 can be the outermost extended surfaces and outer enclosure extended surfaces 568 can be disposed outside of outer anode extended surfaces 348. This can maximize the number of extended surfaces included in the X-ray tube 500 and can maximize heat dissipation from the anode assembly 306 to the enclosure 502 through the anode extended surfaces 348 and the enclosure extended surfaces 568. It should be understood the number of anode extended surfaces 348 and enclosure extended surfaces 568 can vary depending on the application of the X-ray tube 500.

In more detail, heat generated from bombardment of the anode assembly 306 by electrons and the production of X-rays can be transferred from the target surface 354, through the body portion 350, to the anode extended surfaces 348. Heat can be transferred within the anode assembly 306 through conductive heat transfer and the like. The anode extended surfaces 348 can then radiate heat to the enclosure extended surfaces 568. Thus, heat can be transferred from the anode assembly 306 through the anode extended surfaces 348 to the enclosure 502 through the enclosure extended surfaces 568. Heat can be transferred from the enclosure extended surfaces 568 to the body portion 514 and to an environment surrounding the X-ray tube 500. In one or all examples, the X-ray tube 500 can include extended surfaces 118, which can be the same as or similar to the extended surfaces 118 discussed above with respect to FIGS. 1A-1C. In one or all examples, the X-ray tube 500 can include a fan, such as the fan 244 discussed above with respect to FIGS. 2A-2C. By including any combinations of anode extended surfaces 348, enclosure extended surfaces 568, extended surfaces 118, and/or a fan 244 (or other active cooling applied to the exterior of the X-ray tube 500), heat transfer and heat dissipation from the X-ray tube 500 can be increased. By increasing heat dissipation from the X-ray tube 500, performance of the X-ray tube 500 can be increased. The anode extended surfaces 348, enclosure extended surfaces 568, extended surfaces 118, and the fan 244 can be relatively low-cost, low-weight methods for cooling the X-ray tube 500.

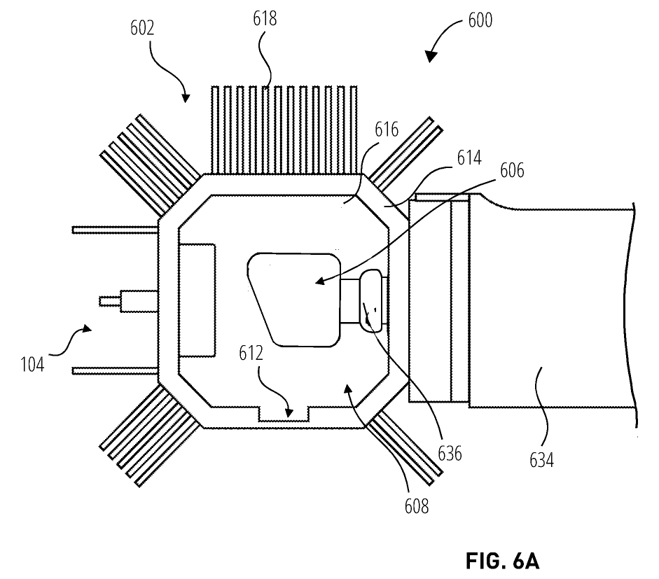

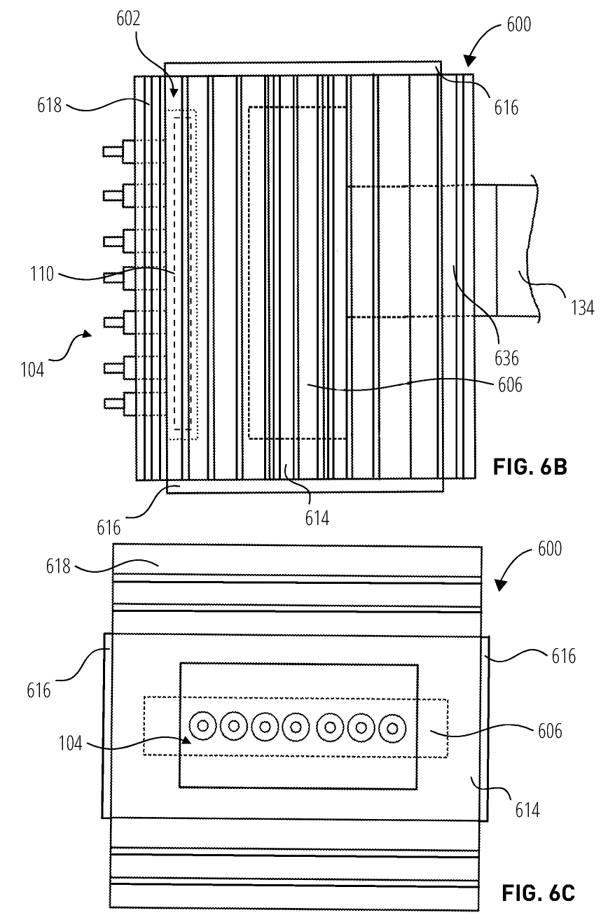

FIGS. 6A-6C illustrate various views of an X-ray tube 600. FIG. 6A is a side view, FIG. 6B is a top-down view, and FIG. 6C is a front-to-back view of the X-ray tube 600. The X-ray tube 600 can be the same as or similar to the X-ray tubes 100, 200, discussed above. FIGS. 6A-6C illustrate an example in which an enclosure 602 of the X-ray tube 600 (including a body portion 614 and end caps 616) has an octagonal shape in a cross-sectional or side view and an anode assembly 606, a connector 636, and a cable 634 are connected to the enclosure 602 through a sidewall of the enclosure 602. Components of the X-ray tube 600 that are the same as or similar to components of the X-ray tube 100 are indicated with the same reference numbers as FIGS. 1A-1C, and additional description of these components is omitted for simplicity.

The X-ray tube 600 can be used to generate X-rays. For example, the X-ray tube 600 can include a cathode assembly 104 and an anode assembly 606 positioned within an enclosure 602, which can maintain an ultra-high vacuum (UHV), an extreme high vacuum (XHV), a high vacuum (HV), or other suitable vacuum levels in an evacuated enclosure 608. A high voltage can be applied between the cathode assembly 104 and the anode assembly 606 such that electrons are emitted from a cathode 110 of the cathode assembly 104 towards a target surface on the anode assembly 606. The anode assembly 606 can be the same as or similar to the anode assemblies 106, 206, 306, 406, discussed above. X-rays can be generated as the electrons impact the target surface on the anode assembly 606 and the X-rays can be emitted from the X-ray tube 600 through an X-ray window 612. The X-ray window 612 can be defined in the enclosure 602.

The body portion 614 of the enclosure 602 can have a rectangular shape in a top-down view (e.g., FIG. 6B) and a front-to-back view (e.g., FIG. 6C). The body portion 614 can have an octagonal or another polygonal shape in a cross-sectional or side view (e.g., FIG. 6A). An opening in the body portion 614 can have an octagonal or another polygonal shape in the cross-sectional or side view. The opening can house components of the X-ray tube 600. The body portion 614 can have a constant thickness, except in portions of the body portion 614 that are machined to house or define components of the X-ray tube 600, such as the cathode assembly 104, the anode assembly 606, the X-ray window 612, and the like. The end caps 616 can have shapes that complement the cross-sectional shape of the body portion 614. For example, the end caps 616 can have octagonal or other polygonal shapes in the side view illustrated in FIG. 6A. In other words, the end caps 616 can have the same outlines or boundaries as the body portion 614. The body portion 614 and the end caps 616 can have any suitable thickness, which can be dependent on the application for the X-ray tubes 600.

The evacuated enclosure 608 of the X-ray tube 600 can be defined by the enclosure 602. For example, the end caps 616 can define two sided surfaces of the evacuated enclosure 608, the body portion 614 can define six side surfaces of the evacuated enclosure 608, the body portion 614 can define a top surface of the evacuated enclosure 608, the body portion 614 can define a bottom surface of the evacuated enclosure 608. In other words, the end caps 616 can define two surface of the evacuated enclosure 608 and the body portion 614 can define eight surfaces of the evacuated enclosure 608. The body portion 614 of the cathode assembly 104 can be coupled to the body portion 614 through an opening defined in a side surface of the body portion 14. The cable 134 and the connector 136 can be coupled to one another through an opening defined in a side surface of the body portion 114, and the anode assembly 106 can be coupled to the side surface of the body portion 114 through the connector 136. As illustrated, the anode assembly 606, the cable 634, and the connector 636 can be positioned through the side of the body portion 614 opposite of the cathode assembly 604.

By forming the enclosure 602 with an octagonal shape, wasted space can be eliminated from the enclosure 602. This can reduce a volume of the evacuated enclosure 608 defined by the enclosure 602 and reduce electrical standoff, which can increase performance of the X-ray tube 600. Further, weight of the enclosure 602 can be reduced. The octagonal shape of the enclosure 602 still provides flat surfaces for components of the X-ray tube 600 to be mounted to within the enclosure 602.

As illustrated in FIGS. 6A-6C, the X-ray tube 600 can include extended surfaces 618. The extended surfaces 618 can be the same as or similar to the extended surfaces 118, discussed above. The extended surfaces 618 can extend from top surfaces, bottom surfaces, side surfaces, diagonal surfaces (e.g., between side surfaces and top surfaces or bottom surfaces), and the like of the body portion 614 of the enclosure 602. As discussed in reference to other examples, the extended surfaces 618 can extend from any surfaces of the body portion 614 that are free from or do not otherwise interfere with components of the X-ray tube 600. For example, the extended surfaces 618 can extend from surfaces of the body portion 614, except where the cathode assembly 104 and the anode assembly 606 are connected to the body portion 614 and the X-ray window 612 is defined in the body portion 614. Providing a larger number of the extended surfaces 618 can increase heat dissipation from the X-ray tube 600.

Although not separately illustrated, in one or all examples, the X-ray tube 600 can further include extended surfaces positioned within the evacuated enclosure 608. For example, the anode assembly 606 can include anode extended surfaces and the body portion 614 can include enclosure extended surfaces, as discussed above. In the side view illustrated in FIG. 6A, the anode extended surfaces can extend upward from a body portion of the anode assembly 606 and the enclosure extended surfaces can extend downward from a top surface of the body portion 614. Thus, the anode extended surfaces, and the enclosure extended surfaces can be positioned outside of paths of electrons and X-rays in the evacuated enclosure 608 and outside of the connector 636 for the anode assembly 606.

Although rounded, circular, rectangular, and octagonal shapes are illustrated for the X-ray tubes of the present disclosure, the teachings of the present disclosure can be applied to X-ray tubes, enclosures, and anode assemblies with any shapes. For example, the enclosures of X-ray tubes can have rounded, circular, rectangular, hexagonal, triangular, octagonal, curved, or any other desired cross-sectional, side, top-down, and front-to-back shapes. Similarly, the anode assemblies of X-ray tubes can have rounded, circular, rectangular, hexagonal, triangular, octagonal, curved, or any other desired cross-sectional, side, top-down, and front-to-back shapes. Enclosures with any shapes can include extended surfaces on exterior surfaces thereof to increase heat dissipation from the enclosures. Fans or other cooling can be supplied to the exteriors of any X-ray tubes. Enclosures with any shapes can include extended surfaces on interior surfaces thereof to increase heat radiation from anode assemblies positioned therein. Anode assemblies with any shapes can include extended surfaces on exterior surfaces thereof (e.g., on any surfaces outside of electron and X-ray paths) to increase heat radiation from the anode assemblies. Any or all of these configurations can be applied to X-ray tubes in order to increase heat dissipation therefrom, allowing for increased performance, while minimizing cost and weight.

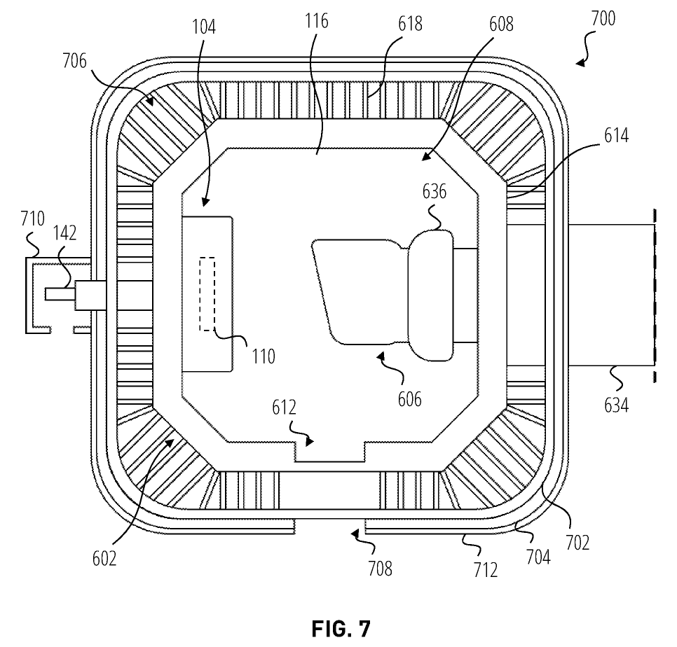

FIG. 7 illustrates a side view of an X-ray tube 700. The X-ray tube 700 can be the same as or similar to the X-ray tube 600, discussed above in reference to FIGS. 6A-6C, except that the X-ray tube 700 further includes an outer enclosure 702 and a shield 704 (also referred to as an enclosure, a lead-lined enclosure, a box, a lead-lined box, or the like). Components of the X-ray tube 700 that are the same as or similar to components of the X-ray tubes 100, 600 are indicated with the same reference numbers as FIGS. 1A-1C and 6A-6C, and additional description of these components is omitted for simplicity. Any of the X-ray tubes described herein can include outer enclosures and/or shields the same as or similar to the outer enclosure 702 and the shield 704.

As illustrated in FIG. 7, the outer enclosure 702 can at least partially surround or encircle the enclosure 602. The outer enclosure 702 can be included to define ducts 706 between the outer enclosure 702, a body portion 614 of the enclosure 602, and extended surfaces 618 protruding outwards from the body portion 614. By defining the ducts 706 between the outer enclosure 702, the extended surfaces 618, and the body portion 614, cooling fluids can be forced through the ducts 706 at higher speeds, in closer proximity to the enclosure 602, improving heat dissipation from the enclosure 602 to the cooling fluids. Cooling fluids that flow through the ducts 706 can include air, or liquid coolants in examples in which weight is less of a concern. The extended surfaces 618 can be shaped or formed to fit tightly in an opening defined by the outer enclosure 702. For example, some or all of the extended surface 618 can contact interior surfaces of the outer enclosure 702. As illustrated in FIG. 7, the outer enclosure 702 can surround or encircle the enclosure 602 in a side view or a cross-sectional view. The outer enclosure 702 can also surround or encircle the enclosure 602 in perpendicular cross-sectional or side views. The outer enclosure 702 can extend in a path of X-rays exiting an X-ray window 612 of the X-ray tube 700 and can be formed from materials that are transparent to X-rays or provide a desired level of attenuation for X-rays. For example, in one or all examples, the outer enclosure 702 can be formed from materials that provide a desired level of attenuation for X-rays and the outer enclosure 702 can act as a filter for X-rays exiting the enclosure 602.

The shield 704 can at least partially surround or encircle the outer enclosure 702. The shield 704 can be formed from radiation shielding or radiation blocking materials, such as lead, tungsten, lead composites, or other radiation shielding materials. The shield 704 can include an opening 708, which can be aligned with the X-ray window 612. The opening 708 can allow X-rays that pass through the X-ray window 612 to exit the shield 704. Caps 710 can be coupled to the shield 704 around components of the X-ray tube 700, such as the vacuum feedthroughs 142, to prevent any leakage of radiation at connections to the X-ray tube 700. The caps 710 can be formed from radiation shielding materials the same as or similar to the shield 704. Further, a coating 712 can be provided around the shield 704. The coating 712 can be a paint, a coating, a clad material, or the like, which can protect the shield 704 and protect users from contacting or being exposed to the materials of the shield 704. The opening 708 can extend through the coating 712. The coating 712 can be applied to the caps 710.

The extended surfaces 618 can protrude from the body portion 614 of the enclosure 602 between the body portion 614 and the outer enclosure 702. The extended surfaces 618 can be provided in any locations that do not interfere with components of the X-ray tube 700. For example, as illustrated in FIG. 7, the extended surfaces 618 can be provided to surround or encircle the body portion 614, except in areas through which vacuum feedthroughs 142 extend, areas around the X-ray window 612, and areas around a cable 134 that supplies power to an anode assembly 606. The number and positioning of the extended surfaces 618 can be maximized to increase heat dissipation from the enclosure 602. However, weight considerations, component location considerations, and the like can reduce the number and location of the extended surfaces 618 provided.

The foregoing description, for purposes of explanation, used specific nomenclature to provide a thorough understanding of the described embodiments. However, it will be apparent to one skilled in the art that the specific details are not required to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. An X-ray tube comprising:
an anode assembly;
a cathode assembly comprising a plurality of electron emission sources configured to emit electrons towards a plurality of focal spots on the anode assembly;
an enclosure at least partially surrounding the cathode assembly and the anode assembly; and
a plurality of surfaces protruding from an exterior surface of the enclosure.

2. The X-ray tube of claim 1, wherein the enclosure and the plurality of surfaces comprise a single, continuous material.

3. The X-ray tube of claim 1, wherein at least one of the plurality of surfaces is coupled to the enclosure by a braze or weld.

4. The X-ray tube of claim 1, wherein at least one of the plurality of surfaces comprises a material different from a material of the enclosure.

5. The X-ray tube of claim 1, further comprising a fan coupled to the enclosure.

6. The X-ray tube of claim 5, wherein the fan is coupled to at least one of the plurality of surfaces.

7. The X-ray tube of claim 1, wherein:
the enclosure comprises a longitudinal body; and
the anode assembly is coupled to an end of the longitudinal body.

8. The X-ray tube of claim 1, wherein the enclosure defines an X-ray window.

9. The X-ray tube of claim 1, further comprising an outer enclosure at least partially surrounding the enclosure and the plurality of surfaces, wherein a duct is defined between the outer enclosure, the enclosure, and the plurality of surfaces.

10. The X-ray tube of claim 9, further comprising a shield at least partially surrounding the outer enclosure, the shield comprising a radiation shielding material.

11. A method of manufacturing an enclosure for an X-ray tube, the method comprising:
forming an enclosure comprising a plurality of extended surfaces extending from a body portion of the enclosure; and
welding an end cap to the body portion of the enclosure.

12. The method of claim 11, wherein the extended surfaces and the body portion of the enclosure are co-formed by extrusion.

13. The method of claim 11, wherein forming the enclosure comprises brazing or welding the extended surfaces to the body portion.

14. The method of claim 11, further comprising coating an interior surface of the enclosure with a material having an emissivity greater than a material of the enclosure.

15. The method of claim 14, further comprising machining an X-ray window into the enclosure after coating the interior surface of the enclosure.

16. An X-ray source comprising:
an enclosure;
a cathode assembly at least partially within the enclosure; and
an anode assembly at least partially within the enclosure, the anode assembly comprising a plurality of anode extended surfaces extending from a body portion of the anode assembly towards the enclosure.

17. The X-ray source of claim 16, wherein the cathode assembly is coupled to the enclosure and comprises a plurality of cathode electron sources.

18. The X-ray source of claim 17, wherein:
the plurality of cathode electron sources defines a plurality of focal spots on a target surface of the anode assembly; and
the extended surfaces extend away from the target surface.

19. The X-ray source of claim 16, wherein the enclosure comprises a plurality of enclosure extended surfaces extending from a body portion of the enclosure towards the anode assembly.

20. The X-ray source of claim 19, wherein an anode extended surface of the plurality of anode extended surfaces is between two enclosure extended surfaces of the plurality of enclosure extended surfaces.
